(19) United States
(12) Patent Application Publication
(10) Pub. No.: US 2017/0005015 A1
(43) Pub. Date: Jan. 5, 2017

(54) MONITOR PROCESS FOR LITHOGRAPHY AND ETCHING PROCESSES

(71) Applicant: United Microelectronics Corp., Hsin-Chu City (TW)

(72) Inventors: Jhen-Cyuan Li, New Taipei City (TW); Yi-Lin Chen, New Taipei City (TW); Shui-Yen Lu, Tainan City (TW)

(21) Appl. No.: 14/791,241

(22) Filed: Jul. 2, 2015

(51) Int. Cl. H01L 21/66; H01L 21/027; H01L 21/306; H01L 23/544; H01L 21/8238

(52) U.S. Cl. CPC H01L 22/12; H01L 23/544; H01L 21/8238; H01L 21/30604; H01L 21/0273; H01L 2223/54426; H01L 2223/54406

(57) ABSTRACT

A monitor process for lithography and etching processes includes the following steps. A first lithography process and a first etching process are performed to define a first alignment mark having a first direction portion orthogonal to a second direction portion. A second lithography process is performed to overlap a part of the first direction portion as well as a part of the second direction portion, thereby maintaining an exposed area of the first alignment mark having a first corresponding direction portion and a second corresponding direction portion. A first critical dimension of the first corresponding direction portion and a second critical dimension of the second corresponding direction portion are measured.

### BACKGROUND OF THE INVENTION

### 1. Field of the Invention

The present invention relates generally to a monitor process for lithography and etching processes, and more specifically to a monitor process for overlapping lithography and etching processes.

### 2. Description of the Prior Art

A lithography and etching process provides a desired pattern onto a substrate or part of a substrate. A lithography and etching process may be used, for example, in the manufacture of integrated circuits (ICs), flat panel displays and other devices or structures having fine features. In a conventional lithography and etching process, a patterning device, which may be referred to as a mask or a reticle, may be used to generate a circuit pattern corresponding to an individual layer of the IC, flat panel display, or other device. This pattern may transferred on (part of) the substrate (e.g. silicon wafer or a glass plate), e.g. via imaging onto a thin film of radiation-sensitive material (photoresist) provided on the substrate.

The lithography and etching process may thus include forming a thin film of a photoresist composition on a substrate such as a silicon wafer, irradiating the film with active light such as ultraviolet rays through a mask pattern, developing the photoresist pattern, and etching the substrate such as a silicon wafer by using the resulting photoresist pattern as a protection film. With the increasing density of semiconductor devices in recent years, the active light used have been changed to those at shorter wavelengths from KrF excimer laser (248 nm) to ArF excimer laser (193 nm).

Accordingly, the substrate may undergo various procedures while applying the lithography and etching process, such as priming, resist coating and a soft bake. After exposure, the substrate may be subjected to other procedures, such as a post-exposure bake (PEB), development, a hard bake and measurement/inspection of the imaged features. This array of procedures is used as a basis to pattern an individual layer of a device, e.g. an IC. Such a patterned layer may then undergo various processes such as etching, ion-implantation (doping), metallization, oxidation, chemo-mechanical polishing, etc., all intended to finish off an individual layer. If several layers are required, then the whole procedure, or a variant thereof, will have to be repeated for each new layer.

### SUMMARY OF THE INVENTION

The present invention provides a monitor process for lithography and etching processes, which monitors the misalignment between two lithography and etching processes by measuring critical dimensions of an alignment mark formed by the two lithography (and etching) processes.

The present invention provides a monitor process for lithography and etching processes including the following steps. A first lithography process and a first etching process are performed to define a first alignment mark having a first direction portion orthogonal to a second direction portion. A second lithography process is performed to overlap a part of the first direction portion as well as a part of the second direction portion, thereby maintaining an exposed area of the first alignment mark having a first corresponding direction portion and a second corresponding direction portion. A first critical dimension of the first corresponding direction portion and a second critical dimension of the second corresponding direction portion are measured.

According to the above, the present invention provides a monitor process for lithography and etching processes, which performs a first lithography process and a first etching process to define a first alignment mark, performs a second lithography process to overlap a part of the first alignment mark and maintain an exposed area, and measures critical dimensions of the exposed area. Hence, variations of these critical dimensions and predetermined critical dimensions can be obtained. Thus, targets accompany with the first alignment mark formed by the first and the second lithography processes and the first etching process can be monitored and corrected.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a flow chart of a monitor process for lithography and etching processes according to an embodiment of the present invention.

FIG. 2 schematically depicts top views of a monitor process for lithography and etching processes according to an ideal embodiment of the present invention.

FIG. 3 schematically depicts top views of a monitor process for lithography and etching processes according to a first embodiment of the present invention.

FIG. 4 schematically depicts top views of a monitor process for lithography and etching processes according to a second embodiment of the present invention.

FIG. 5 schematically depicts top views of a semiconductor process applying the monitor process of FIG. 1.

FIG. 6 schematically depicts top views of a semiconductor process applying the monitor process of FIG. 1.

### DETAILED DESCRIPTION

A monitor process presented as follows can be applied in many semiconductor processes, which include alignment issues between at least two lithography and etching processes; for example, a boundary alignment between two lithography and etching processes processed in two adjacent areas having a boundary in between, a double patterning process, or others.

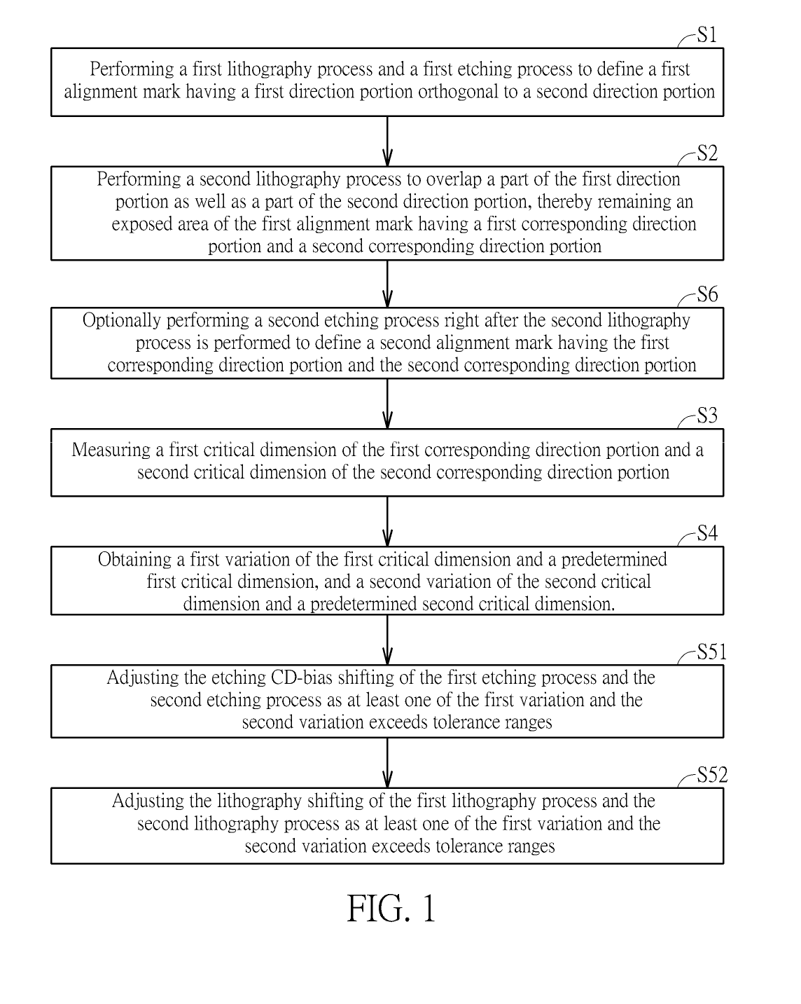

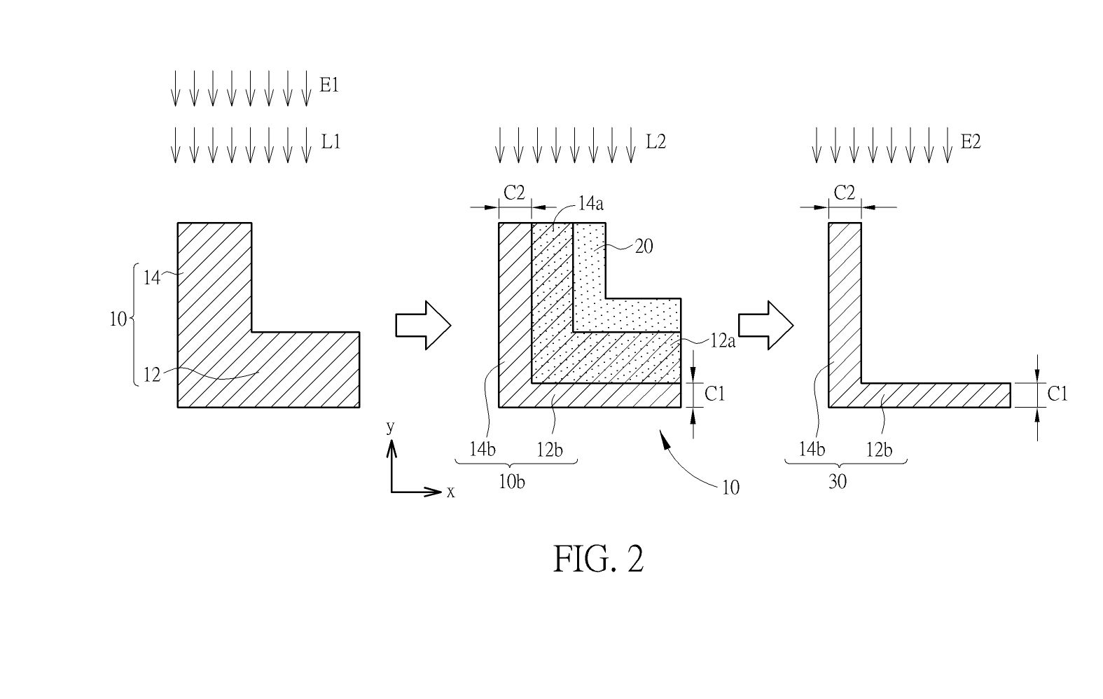

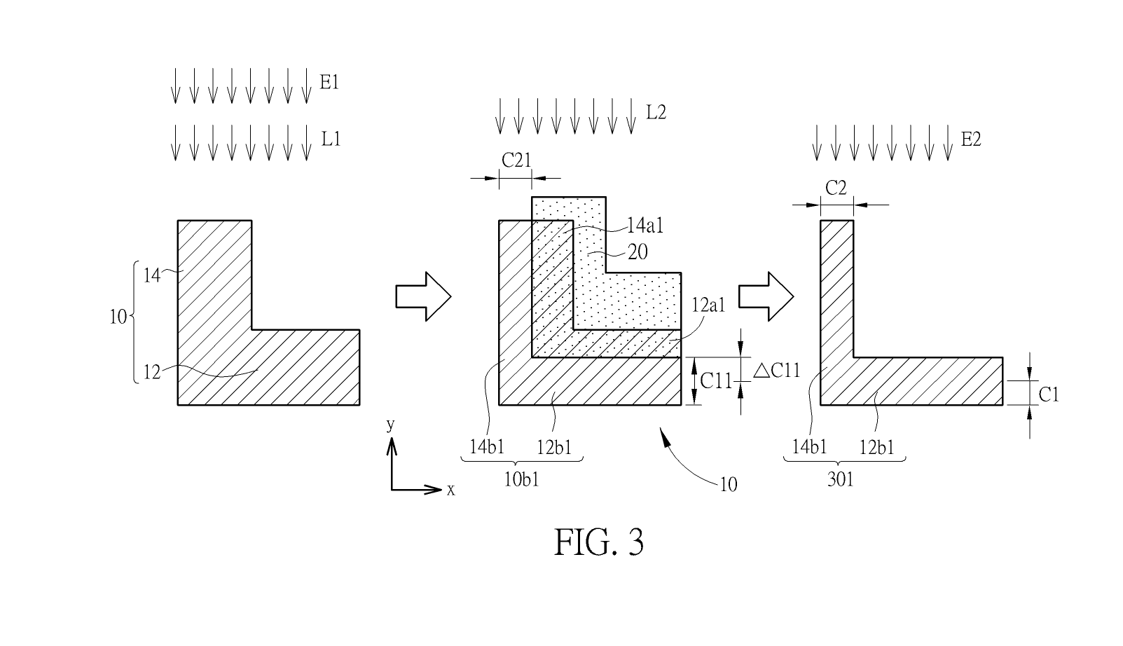

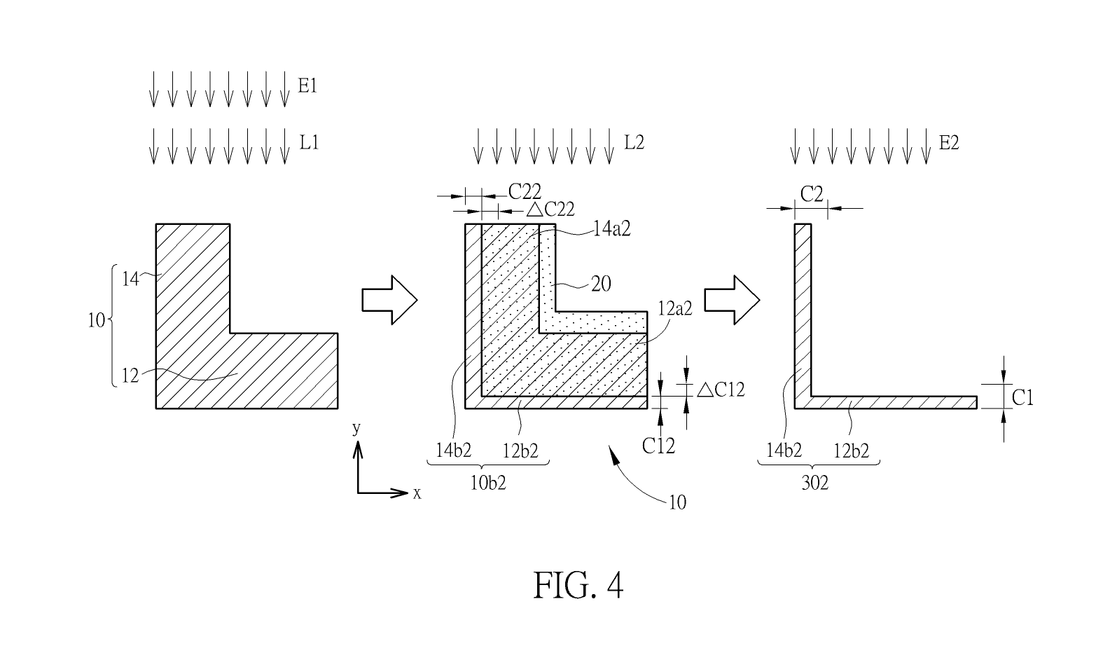

FIG. 1 schematically depicts a flow chart of a monitor process for lithography and etching processes according to an embodiment of the present invention. FIG. 2 schematically depicts top views of a monitor process for lithography and etching processes according to an ideal embodiment of the present invention. FIG. 3 schematically depicts top views of a monitor process for lithography and etching processes according to a first embodiment of the present invention. FIG. 4 schematically depicts top views of a monitor process for lithography and etching processes according to a second embodiment of the present invention. FIGS. 2-4 represent three cases of the present invention individually, which have common monitor processes of FIG. 1 and thus are described simultaneously.

According to step S1 of FIG. 1—performing a first lithography process and a first etching process to define a first alignment mark having a first direction portion orthogonal to a second direction portion, please refer to the left diagrams of FIG. 2, FIG. 3 and FIG. 4. A first lithography process L1 and a first etching process E1 are performed to define a first alignment mark 10. In these embodiments, the first alignment mark 10 is an L-shaped alignment mark, but it is not limited thereto. In other embodiments, the first alignment mark 10 may have other shapes, depending upon practical requirements. As the monitor process of the present invention is applied to targets (not shown) such as hard masks or other material layers aligning and forming, the first alignment mark 10 preferably has materials common to the targets. That is, as the targets are composed of nitride, the first alignment mark 10 is preferably a nitride alignment mark, but it is not limited thereto. In this way, as the first lithography process L1 and the first etching process E1 are performed to form the targets, the first alignment mark 10 can be formed as well. The first alignment mark 10 is thus a testkey in a scribe line, for testing the alignment of the targets.

The first alignment mark 10 has a first direction portion 12 and a second direction portion 14. It is emphasized that, the first direction portion 12 is orthogonal to the second direction portion 14 for respectively testing the alignments of the targets in two orthogonal directions. This means as the first direction portion 12 is an x-direction portion, the second direction portion 14 is a y-direction portion. When related data about the alignment issues such as the shiftings of the targets in two orthogonal directions are obtained, the alignment issues such as the shifting of the targets in a plane can be monitored, and sequential solving methods can be processed to correct lithography processes or/and etching processes performed on the targets. Furthermore, the first alignment mark 10 is an etching remaining area in this case, but the first alignment mark 10 may be an etching area instead in another case, depending upon process requirements.

According to step S2 of FIG. 1—performing a second lithography process to overlap a part of the first direction portion as well as apart of the second direction portion, thereby maintaining an exposed area of the first alignment mark having a first corresponding direction portion and a second corresponding direction portion, please refer to the middle diagrams of FIG. 2, FIG. 3 and FIG. 4. A second lithography process L2 is performed, thereby a photoresist layer 20 partially covers the first alignment mark 10. As shown in FIG. 2, in an ideal case, the photoresist layer 20 only overlaps a part 12a of the first direction portion 12 as well as a part 14a of the second direction portion 14, to expose an exposed area 10b for measuring. The exposed area 10b may include a first corresponding direction portion 12b and a second corresponding direction portion 14b. As shown in FIG. 3, in a first practical case, the photoresist layer 20 only overlaps a part 12a1 of the first direction portion 12 as well as apart 14a1 of the second direction portion 14, to expose an exposed area 10b1 for measuring. The exposed area 10b1 may include a first corresponding direction portion 12b1 and a second corresponding direction portion 14b1. As shown in FIG. 4, in a second practical case, the photoresist layer 20 only overlap a part 12a2 of the first direction portion 12 as well as apart 14a2 of the second direction portion 14, to expose an exposed area 10b2 for measuring. The exposed area 10b2 may include a first corresponding direction portion 12b2 and a second corresponding direction portion 14b2.

It is noted that, the photoresist layer 20 of the present invention must only overlap a part 12a/12a1/12a2 of the first direction portion 12 as well as a part 14a/14a1/14a2 of the second direction portion 14 to reserve an exposed area 10b/10b1/10b2 for measuring. More precisely, the exposed area 10b/10b1/10b2 may include a first corresponding direction portion 12b/12b1/12b2 and a second corresponding direction portion 14b/14b1/14b2, which reveal the alignment issues such as the shiftings of the targets in two orthogonal directions individually. Then, specific data about the alignment issues such as the shiftings of the targets can be obtained through the following steps.

According to step S3 of FIG. 1—measuring a first critical dimension of the first corresponding direction portion and a second critical dimension of the second corresponding direction portion, please refer to the middle diagrams of FIG. 2, FIG. 3 and FIG. 4. As shown in the middle diagram of FIG. 2, the first critical dimension C1 of the first corresponding direction portion 12b and a second critical dimension C2 of the second corresponding direction portion 14b are measured by methods such as optical measuring methods, for example, a scanning electron microscope (SEM) method. Due to the embodiment depicted in FIG. 2 being an ideal case, the first critical dimension C1 of the first corresponding direction portion 12b equals to a predetermined first critical dimension while the second critical dimension C2 of the second corresponding direction portion 14b equals to a predetermined second critical dimension, wherein the predetermined first critical dimension and the predetermined second critical dimension are decided in previous layout design steps. In this case, the predetermined first critical dimension and the predetermined second critical dimension are at a range of 20-30 nanometers, but it is not limited thereto.

Likewise, as shown in the middle diagram of FIG. 3, a first critical dimension C11 of the first corresponding direction portion 12b1 and a second critical dimension C21 of the second corresponding direction portion 14b1 are measured. As shown in the middle diagram of FIG. 4, a first critical dimension C12 of the first corresponding direction portion 12b2 and a second critical dimension C22 of the second corresponding direction portion 14b2 are measured.

According to step S4 of FIG. 1—obtaining a first variation of the first critical dimension and a predetermined first critical dimension, and a second variation of the second critical dimension and a predetermined second critical dimension, please refer to the middle diagrams of FIG. 2, FIG. 3 and FIG. 4. Since the embodiment of FIG. 2 is an ideal case, the first practical case of FIG. 3 and the second practical case of FIG. 4 can be compared to the ideal case of FIG. 2, which has the first critical dimension C1 equal to the predetermined first critical dimension and the second critical dimension C2 equal to the predetermined second critical dimension, to get the variation between the practical cases and the ideal case.

According to the first practical case of FIG. 3, a first variation ΔC11 of the first critical dimension C11 and a predetermined first critical dimension (C1) can be obtained, and a second variation of the second critical dimension C21 and a predetermined second critical dimension (C2) is zero in this case. That is, the photoresist layer 20 in the first practical case of FIG. 3 shifts in y-direction without shifting in x-direction.

According to the second practical case of FIG. 4, a first variation ΔC12 of the first critical dimension C12 and a predetermined first critical dimension (C1) can be obtained, while a second variation ΔC22 of the second critical dimension C22 and a predetermined second critical dimension (C2) is obtained. In this case, the photoresist layer 20 shifts not only in x-direction but also in y-direction.

When the shifting values of FIG. 3/FIG. 4 are obtained, sequential solving methods can be processed to correct lithography processes or/and etching processes as the first variation ΔC11/ΔC12 or/and the second variation ΔC22 exceed tolerance ranges, which are values depending and deciding upon practical circumstances or device performance demands. Additionally, as the first variation ΔC11/ΔC12 or/and the second variation ΔC22 fall into tolerance ranges, sequential semiconductor processes can be kept on.

Two ways are presented as follows to correct lithography processes or/and etching processes, but it is not limited thereto. Other ways may be processed according to the first variation ΔC11/ΔC12 or/and the second variation ΔC22 got by the process of the present invention.

According to step S51 of FIG. 1—adjusting the etching CD-bias shifting of the first etching process as at least one of the first variation and the second variation exceeds tolerance ranges. The method of adjusting the etching CD-bias shifting of the first etching process E1 is preferably applied in the second practical case of FIG. 4, which has the photoresist layer 20 shifting not only in x-direction but also in y-direction, because wrong etching CD-bias of an etching process often causes the photoresist layer 20 shifting in both x and y direction, but it is not limited thereto.

According to step S52 of FIG. 1—adjusting the lithography shifting of the first lithography process and the second lithography process as at least one of the first variation and the second variation exceeds tolerance ranges. The method of adjusting the lithography shifting of the first lithography process L1 and the second lithography process L2 is preferably applied in the first practical case of FIG. 3, which has the photoresist layer 20 shifting only in y-direction, because the lithography shifting of an lithography process often causes the photoresist layer 20 to shift in one direction, but it is not limited thereto.

Additionally, the step S51 of FIG. 1—adjusting the etching CD-bias shifting of the first etching process as at least one of the first variation and the second variation exceeds tolerance ranges may be applied in the first practical case of FIG. 3 instead or also applied in the first practical case of FIG. 3 as the step S52 is applied. The step S52 of FIG. 1—adjusting the lithography shifting of the first lithography process and the second lithography process as at least one of the first variation and the second variation exceeds tolerance ranges maybe applied in the second practical case of FIG. 4 instead or also applied in the second practical case of FIG. 4 as the step S51 is applied.

Furthermore, after the shifting values of FIG. 3/FIG. 4 are obtained in the step S4 of FIG. 1, the photoresist layer 20 can be removed as the shifting values such as the first variation ΔC11/ΔC12 or/and the second variation ΔC22 of FIG. 3/FIG. 4 exceeds tolerance ranges to rework the step S2 (performing a second lithography process to overlap a part of the first direction portion as well as apart of the second direction portion, thereby maintaining an exposed area of the first alignment mark having a first corresponding direction portion and a second corresponding direction portion) after adjusting according to the solving methods such as the step 51 or/and the step 52.

According to the above, the steps S3, S4, S51 and S52 all processed right after the photoresist layer 20 is covered while the second lithography process L2 is performed without etching first, so that the photoresist layer 20 can be removed to rework the step S2, S3, S4, S51 and S52 as needed. However, in other cases, a second etching process may be performed right after the second lithography process L2 is performed to directly define a second alignment mark having the first corresponding direction portion 12b/12b1/12b2 and the second corresponding direction portion 14b/14b1/14b2.

According to step SE of FIG. 1—optionally performing a second etching process right after the second lithography process is performed to define a second alignment mark having the first corresponding direction portion and the second corresponding direction portion S6, please refer to the right diagrams of FIG. 2 FIG. 3 and FIG. 4 in the following. A second etching process E2 is performed right after the second lithography process L2 is performed, therefore a second alignment mark 30 being formed as shown in FIG. 2, a second alignment mark 301 being formed as shown in FIG. 3, and a second alignment mark 302 being formed as shown in FIG. 4. In this embodiment, the part 12a/12a1/12a2 of the first direction portion 12 and the part 14a/14a1/14a2 of the second direction portion 14 covered by the photoresist layer 20 are etched with the other areas not covered by the photoresist layer 20 being maintained. In another embodiment, the part 12a/12a1/12a2 of the first direction portion 12 and the part 14a/14a1/14a2 of the second direction portion 14 covered by the photoresist layer 20 maybe maintained with the other areas not covered by the photoresist layer 20 being etched, depending upon the first alignment mark 10 being an etching remaining area or an etching area.

More precisely, the second alignment mark 30 has the first corresponding direction portion 12b and the second corresponding direction portion 14b; the second alignment mark 301 has the first corresponding direction portion 12b1 and the second corresponding direction portion 14b1; and the second alignment mark 302 has the first corresponding direction portion 12b2 and the second corresponding direction portion 14b2. Thereafter, the step S3: measuring a first critical dimension of the first corresponding direction portion and a second critical dimension of the second corresponding direction portion, the step S4: obtaining a first variation of the first critical dimension and a predetermined first critical dimension, and a second variation of the second critical dimension and a predetermined second critical dimension, the step S51: adjusting the etching CD-bias shifting of the first etching process as at least one of the first variation and the second variation exceeds tolerance ranges, or/and the step S52: adjusting the lithography shifting of the first lithography process and the second lithography process as at least one of the first variation and the second variation exceeds tolerance ranges, can be performed sequentially just like the way described previously. The only difference may occur in the step S51, such that: since the second etching process E2 is performed, not only can the etching CD-bias shifting of the first etching process be adjusted but also the etching CD-bias shifting of the second etching process E2 can be adjusted as at least one of the first variation and the second variation exceeds tolerance ranges.

The monitor process of the present invention can be applied in many semiconductor processes. For instance, as a boundary alignment between two lithography and etching processes processed in two adjacent areas are carried out, two cases may occur presented in the following. The monitor process of the present invention can be applied in both the two cases.

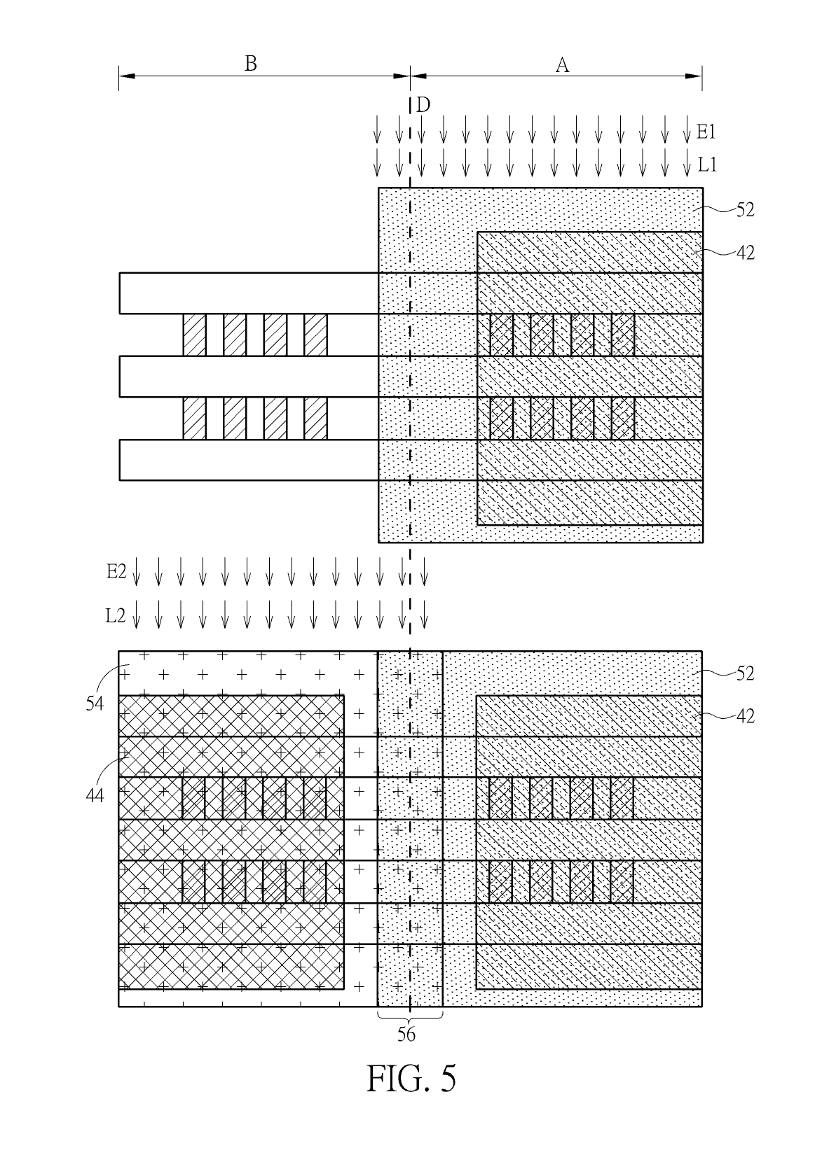

FIG. 5 schematically depicts top views of a semiconductor process applying the monitor process of FIG. 1. In this case, the first lithography process L1 and the first etching process E1 of FIGS. 2-4 are a lithography and etching process performed in a first area A while the second lithography process L2 and the second etching process E2 are a lithography and etching process performed in a second area B.

As shown in the top diagram of FIG. 5, the first area A is a PFET area while the second area B is an NFET area, wherein the first area A and the second area B have a boundary D, but it is not limited thereto. Fins 112a are disposed in the first area A while fins 112b are disposed in the second area B. Gate strings 120 are disposed across the fins 112a and the fins 112b, wherein the gate strings 120 cross the boundary D.

The first lithography process L1 is performed only in the first area A to cover a photoresist layer 42 in the first area A. The first etching process E1 is then performed in an etching area 52, which exceeds the first area A to the second area B in this case. Meanwhile, the first alignment mark 10 of FIGS. 2-4 is formed in a scribe line (not shown).

Thereafter, as shown in the bottom diagram of FIG. 5, the second lithography process L2 is performed only in the second area B to cover a photoresist layer 44 in the second area B. Then, the second etching process E2 is performed in an etching area 54, which exceeds the second area B to the first area A in this case. Meanwhile, the second alignment mark 30 of FIGS. 2-4 is formed in the scribe line (not shown).

Therefore, the etching area 52 and the etching area 54 intersect a double etching area 56 overlapping the boundary D. This double etching area 56 degrading device performance can then be monitored and corrected through the exposed area 10b/10b1/10b2 of the first alignment mask 10 or the second alignment 30/301/302 of FIGS. 2-4, which is formed in the scribe line while the first lithography process L1, the second lithography process L2, the first etching process E1 and the second etching process E2 are performed, analyzing by said method of the present invention.

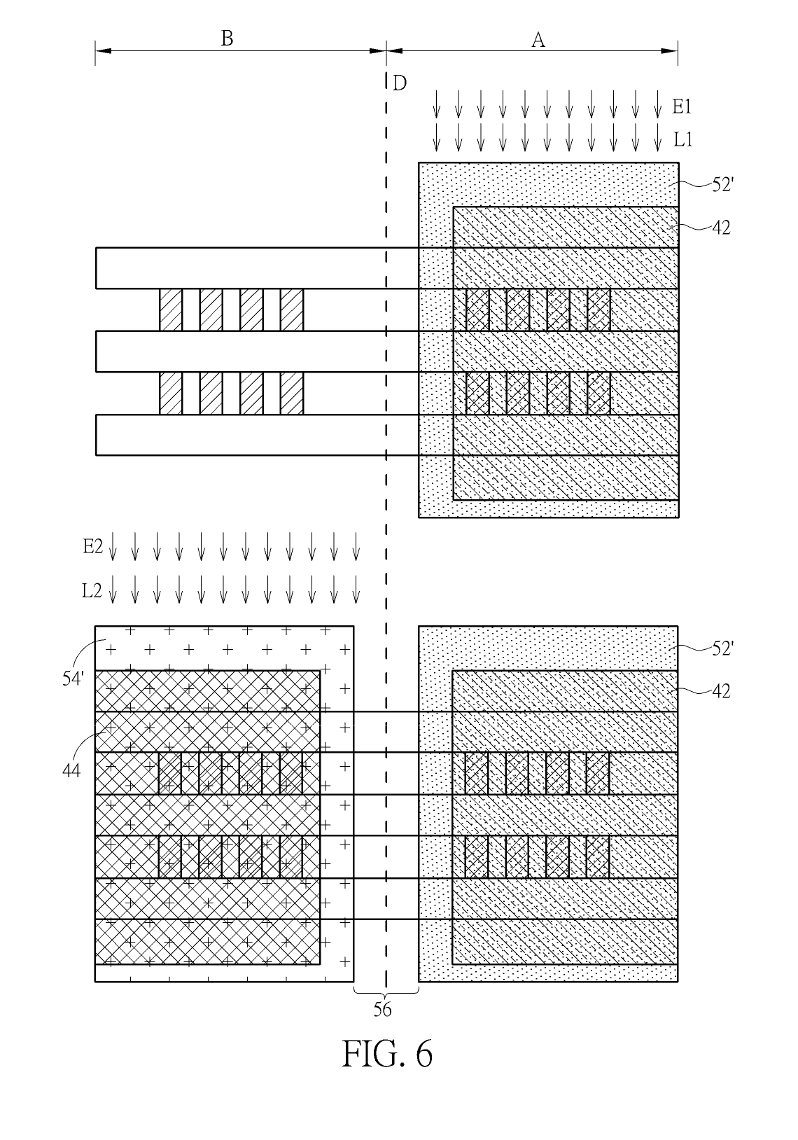

Similarly, FIG. 6 schematically depicts top views of a semiconductor process applying the monitor process of FIG. 1. As shown in the top diagram of FIG. 6, fins 112a are disposed in the first area A while fins 112b are disposed in the second area B. Gate strings 120 are disposed across the fins 112a and the fins 112b, wherein the gate strings 120 cross the boundary D.

The first lithography process L1 is performed only in the first area A to cover a photoresist layer 42 in the first area A. Then, the first etching process E1 is performed in an etching area 52′, which only includes a part of the first area A in this case. Meanwhile, the first alignment mark 10 of FIGS. 2-4 is formed in a scribe line (not shown).

Thereafter, as shown in the bottom diagram of FIG. 6, the second lithography process L2 is performed only in the second area B to cover a photoresist layer 44 in the second area B. Then, the second etching process E2 is performed in an etching area 54′, which only includes a part of the second area B in this case. Meanwhile, the second alignment mark 30 of FIGS. 2-4 is formed in the scribe line (not shown).

Therefore, the etching area 52′ and the etching area 54′ both do not approach the boundary D, leading to a bump maintaining area 56′. The bump maintaining area 56′ degrading device performances can also be monitored and corrected through the exposed area 10b/10b1/10b2 of the first alignment mask 10 or the second alignment 30/301/302 of FIGS. 2-4, analyzing by said method of the present invention.

The two cases of FIGS. 5-6 are just two possible cases occurring in practical circumstances. Many other cases can also be monitored and corrected through the process of the present invention.

To summarize, the present invention provides a monitor process for lithography and etching processes, which performs a first lithography process and a first etching process to define a first alignment mark, performs a second lithography process to overlap a part of the first alignment mark and maintain an exposed area, and measures critical dimensions of the exposed area. Hence, variations of these critical dimensions and predetermined critical dimensions can be obtained. Optionally, a second etching process may be performed after the second lithography process is performed and before the critical dimensions are measured to form a second alignment mark equaling to the exposed area.

As the variations of these critical dimensions and predetermined critical dimensions exceed tolerance ranges, solving steps can be processed. For example, a step of adjusting the lithography shifting of the first lithography process and the second lithography process, or/and a step of adjusting the etching CD-bias shifting of the first etching process (and the second etching process), can be performed. Therefore, targets formed by the first and the second lithography processes and the first and the second etching processes accompany with the first alignment mark usually formed in a scribe line can be monitored and corrected to an applicative situation.

Those skilled in the art will readily observe that numerous modifications and alterations of the device and method may be made while retaining the teachings of the invention. Accordingly, the above disclosure should be construed as limited only by the metes and bounds of the appended claims.

1. A monitor process for lithography and etching processes, comprising:
performing a first lithography process and a first etching process to define a first alignment mark having a first direction portion orthogonal to a second direction portion;
performing a second lithography process to overlap a part of the first direction portion as well as a part of the second direction portion, thereby maintaining an exposed area of the first alignment mark having a first corresponding direction portion and a second corresponding direction portion; and
after the second lithography process being performed, measuring a first critical dimension of the first corresponding direction portion and a second critical dimension of the second corresponding direction portion.

2. The monitor process for lithography and etching processes according to claim 1, further comprising:
obtaining a first variation of the first critical dimension and a predetermined first critical dimension, and a second variation of the second critical dimension and a predetermined second critical dimension.

3. The monitor process for lithography and etching processes according to claim 2, wherein the predetermined first critical dimension and the predetermined second critical dimension are at a range of 20-30 nanometers.

4. The monitor process for lithography and etching processes according to claim 2, further comprising:
performing a second etching process right after the second lithography process is performed to define a second alignment mark having the first corresponding direction portion and the second corresponding direction portion.

5. The monitor process for lithography and etching processes according to claim 4, further comprising:
adjusting the etching CD-bias shifting of the first etching process and the second etching process as at least one of the first variation and the second variation exceeds tolerance ranges.

6. The monitor process for lithography and etching processes according to claim 2, further comprising:
adjusting the lithography shifting of the first lithography process and the second lithography process as at least one of the first variation and the second variation exceeds tolerance ranges.

7. The monitor process for lithography and etching processes according to claim 2, further comprising:
removing a photoresist layer covered while the second lithography process is performed without etching first, as at least one of the first variation and the second variation exceeds tolerance ranges.

8. The monitor process for lithography and etching processes according to claim 1, wherein the first alignment mark comprises an L-shaped alignment mark.

9. The monitor process for lithography and etching processes according to claim 1, wherein the first alignment mark comprises a nitride alignment mark.

10. The monitor process for lithography and etching processes according to claim 1, wherein the first lithography process and the first etching process comprise a lithography and etching process performed in a first area and the second lithography process comprises a lithography process performed in a second area, wherein the first area and the second area have a boundary.

11. The monitor process for lithography and etching processes according to claim 10, wherein the first area is a PFET area while the second area is an NFET area.

12. The monitor process for lithography and etching processes according to claim 1, wherein the second corresponding direction portion is orthogonal to the first corresponding direction portion.
